(19) United States
(12) Patent Application Publication
(10) Pub. No.: US 2013/0056065 A1
(43) Pub. Date: Mar. 7, 2013

(54) TRANSPARENT FILM CONTAINING TETRAFLUOROETHYLENE-HEXAFLUOROPROPYLENE COPOLYMER AND HAVING AN ORGANOSILANE COUPLING AGENT TREATED SURFACE

(71) Applicants: Guangjun Yin, Shanghai (CN); Nicholas J. Glassmaker, Wilmington, DE (US)

(72) Inventors: Guangjun Yin, Shanghai (CN); Nicholas J. Glassmaker, Wilmington, DE (US)

(73) Assignee: E I Duont De Nemours and Company, Willimington, DE (US)

(21) Appl. No.: 13/697,057

(22) PCT Filed: Jun. 7, 2010
(86) PCT No.: PCT/CN10/73607

§ 371 Date: Nov. 9, 2012

(51) Int. Cl. B32B 27/08; H01L 31/0216; B32B 27/28

(52) U.S. Cl. 136/256; 428/422

(57) ABSTRACT

In a first aspect, a transparent film includes a tetrafluoroethylene-hexafluoropropylene copolymer layer having an organosilane coupling agent treated surface such that the treated surface of the transparent film, when directly laminated to an encapsulant layer including ethylene-vinyl acetate copolymer, forms a multilayer film with an average peel strength between the transparent film and the encapsulant layer of greater than 2 lbf/in after curing to crosslink the ethylene-vinyl acetate copolymer and then 1000 hrs of damp heat exposure.

In a second aspect, a weatherable multilayer film includes a transparent film and an encapsulant layer. The transparent film includes a tetrafluoroethylene-hexafluoropropylene copolymer layer having an organosilane coupling agent treated surface. The encapsulant layer is directly laminated to the treated surface of the transparent film. An average peel strength between the transparent film and the encapsulant layer is greater than 2 lbf/in after 1000 hrs of damp heat exposure.

### BACKGROUND INFORMATION

1. Field of the Disclosure

This disclosure relates to a transparent film containing tetrafluoroethylene-hexafluoropropylene copolymer and having an organosilane coupling agent treated surface, a multilayer film, and a photovoltaic module.

2. Description of the Related Art

Photovoltaic (PV) modules (or solar modules) are used to produce electrical energy from sunlight, offering a more environmentally friendly alternative to traditional methods of electricity generation. These modules are based on a variety of semiconductor cell systems that can absorb light and convert it into electrical energy and are typically categorized into two types based on the light absorbing material used, i.e., bulk or wafer-based modules and thin film modules. Typically, an array of individual cells is electrically interconnected and assembled in a module, and an array of modules can be electrically interconnected together in a single installation to provide a desired amount of electricity.

If the light absorbing semiconductor material in each cell, and the electrical components used to transfer the electrical energy produced by the cells, can be suitably protected from the environment, photovoltaic modules can last 25, 30, and even 40 or more years without significant degradation in performance.

Fluoropolymer films are recognized as an important component in photovoltaic modules due to their excellent strength, weather resistance, UV resistance, moisture barrier properties, low dielectric constant, and high break down voltage and can play a role in both wafer-based and thin film modules. In one particular application, a fluoropolymer film, such as an ethylene-tetrafluoroethylene copolymer (ETFE) film, may be used as a frontsheet for a photovoltaic module instead of the more common glass layer. Challenges with using a fluoropolymer film as a frontsheet include providing the desired combination of barrier properties and transparency, as well as providing good adhesion to the (front) encapsulant layer. For instance, higher transparency will improve solar light flux into the cells resulting in greater power output from the module, but achieving higher transparency typically requires thinner films, which reduces strength, weather resistance, UV resistance, and moisture barrier properties. Furthermore, the reduced barrier properties of thinner films can result in faster degradation of the encapsulant layer, further reducing the overall performance of the module. ETFE films have become the most widely used fluoropolymer for PV frontsheet application due to their excellent adhesion to ethylene-vinyl acetate (EVA) copolymer encapsulant sheets, the most commonly used material for the encapsulant layer.

Alternatives to ETFE with higher transparency and/or better barrier properties are desirable, particularly for use in flexible solar cell modules where rigid glass is not feasible. Additionally, the alternatives should have adequate adhesion to encapsulant materials under adverse conditions to enable their use in photovoltaic modules.

EVA copolymers have been favored as encapsulant materials because of their durability, desirable chemical and physical properties, optical clarity and reasonable cost. Encapsulant materials have been compounded with silane coupling agents to improve adhesion to fluoropolymer layers. (See U.S. Pat. Nos. 6,963,120 and 6,762,508, U.S. Patent Application Publications 2009/0183773, 2009/0120489, 2009/0255571, 2008/0169023, 2008/0023063, 2008/0023064, European Patent Application EP1065731, French Patent FR 2539419 and Japanese Patent Applications JP2000/186114, JP2001/144313, JP2004/031445, JP2004/058583, JP2006/032308, JP2006/1690867).

U.S. Pat. No. 6,753,087 discloses a multilayer structure including a fluoropolymer bonded to a substrate prepared by heating a bonding composition including an amino-substituted organosilane to form a bond. U.S. Patent Application Publications 2008/0023063, 2008/0023064, 2008/0264471 and 2008/0264481 describe solar cells in which one or both surfaces of any of the solar cell laminate layers may be treated with a silane coupling agent that incorporates an amine function.

U.S. Pat. No. 7,638,186 and patent application publication EP577985 disclose the use of tetrafluoroethylene-hexafluoropropylene copolymers, commonly referred to as FEP, as backsheet layers in photovoltaic modules. Patent application publication WO2004/019421 discloses FEP used as a frontsheet layer in photovoltaic modules. However, providing durable adhesion of FEP to encapsulant materials, such EVA copolymers, has proved challenging. There is a need for improvement in the long-term durability and performance of modules using FEP in transparent films for frontsheets.

### SUMMARY

The invention provides a transparent film having a tetrafluoroethylene-hexafluoropropylene layer with an organosilane coupling agent treated surface. The transparent film can be directly laminated to an encapsulant layer via the organosilane coupling agent treated surface to form a weatherable multilayer film that may be used as an integrated frontsheet for a photovoltaic module.

In a first aspect, a transparent film includes a tetrafluoroethylene-hexafluoropropylene copolymer layer having an organosilane coupling agent treated surface such that the treated surface of the transparent film, when directly laminated to an encapsulant layer including ethylene-vinyl acetate copolymer, forms a multilayer film with an average peel strength between the transparent film and the encapsulant layer of greater than 2 lbf/in after curing to crosslink the ethylene-vinyl acetate copolymer and then 1000 hrs of damp heat exposure.

In a second aspect, a weatherable multilayer film includes a transparent film and an encapsulant layer. The transparent film includes a tetrafluoroethylene-hexafluoropropylene copolymer layer having an organosilane coupling agent treated surface. The encapsulant layer is directly laminated to the treated surface of the transparent film. An average peel strength between the transparent film and the encapsulant layer is greater than 2 lbf/in after 1000 hrs of damp heat exposure. When the encapsulant layer includes ethylene-vinyl acetate copolymer, the multilayer film is cured to crosslink the ethylene-vinyl acetate copolymer prior to 1000 of damp heat exposure.

In a third aspect, a photovoltaic module includes a frontsheet, a front encapsulant layer, a cell layer, and a backsheet. The frontsheet includes a transparent film including a tetrafluoroethylene-hexafluoropropylene copolymer layer having an organosilane coupling agent treated surface. The front encapsulant layer is directly laminated to the treated surface of the frontsheet. An average peel strength between the frontsheet and the encapsulant layer is greater than 2 lbf/in after 1000 hrs of damp heat exposure.

The foregoing general description and the following detailed description are exemplary and explanatory only and are not restrictive of the invention, as defined in the appended claims.

### DETAILED DESCRIPTION

### Definitions

The following definitions are used herein to further define and describe the disclosure.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

As used herein, the terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

In the present application, the terms “sheet”, “layer” and “film” are used in their broad sense interchangeably. A “frontsheet” is a sheet, layer or film on the side of a photovoltaic module that faces a light source and may also be described as an incident layer. Because of its location, it is generally desirable that the frontsheet has high transparency to the desired incident light. A “backsheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

“Encapsulant” layers are used to encase the fragile voltage-generating solar cell layer to protect it from environmental or physical damage and hold it in place in the photovoltaic module. Encapsulant layers may be positioned between the solar cell layer and the incident layer, between the solar cell layer and the backing layer, or both. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to frontsheets, backsheets, other rigid polymeric sheets and cell surfaces, and good long term weatherability.

An “integrated frontsheet” is a sheet, layer or film that combines an incident layer and an encapsulant layer. An “integrated backsheet” is a sheet, layer or film that combines a backing layer and an encapsulant layer.

The term “copolymer” is used herein to refer to polymers containing copolymerized units of two different monomers (a dipolymer), or more than two different monomers.

In a first aspect, a transparent film includes a tetrafluoroethylene-hexafluoropropylene copolymer layer having an organosilane coupling agent treated surface such that the treated surface of the transparent film, when directly laminated to an encapsulant layer including ethylene-vinyl acetate copolymer, forms a multilayer film with an average peel strength between the transparent film and the encapsulant layer of greater than 2 lbf/in after curing to crosslink the ethylene-vinyl acetate copolymer and then 1000 hrs of damp heat exposure.

In one embodiment of the first aspect, the transparent film has a transmission of greater than 90% in the visible region of the electromagnetic spectrum.

In another embodiment of the first aspect, the organosilane coupling agent treated surface is formed by applying a solution of the organosilane coupling agent to the tetrafluoroethylene-hexafluoropropylene copolymer layer and drying. In a specific embodiment, the solution includes polar organic solvent. In a more specific embodiment, the polar organic solvent includes an alcohol and the alcohol includes 8 or fewer carbon atoms.

In still another embodiment of the first aspect, the organosilane coupling agent treated surface includes an aminosilane. In a specific embodiment, the aminosilane includes 3-aminopropyltrimethoxysilane, 3-aminopropyltriethoxysilane, N,N′-bis[(3-trimethoxysilyl)propyl]ethylenediamine, N-(2-aminoethyl)-3-aminopropyltrimethoxysilane, N-2-(vinylbenzylamino)-ethyl-aminopropyltrimethoxysilane), or mixtures thereof.

In yet another embodiment of the first aspect, the tetrafluoroethylene-hexafluoropropylene copolymer layer has a thickness in the range of 10 to 200 microns.

In a second aspect, a weatherable multilayer film includes a transparent film and an encapsulant layer. The transparent film includes a tetrafluoroethylene-hexafluoropropylene copolymer layer having an organosilane coupling agent treated surface. The encapsulant layer is directly laminated to the treated surface of the transparent film. An average peel strength between the transparent film and the encapsulant layer is greater than 2 lbf/in after 1000 hrs of damp heat exposure. When the encapsulant layer includes ethylene-vinyl acetate copolymer, the multilayer film is cured to crosslink the ethylene-vinyl acetate copolymer prior to 1000 of damp heat exposure.

In one embodiment of the second aspect, the organosilane coupling agent treated surface of the transparent film is formed by applying a solution of the organosilane coupling agent to the tetrafluoroethylene-hexafluoropropylene copolymer layer and drying. In a specific embodiment, the solution of the organosilane coupling agent includes polar organic solvent. In a more specific embodiment, the polar organic solvent includes an alcohol and the alcohol includes 8 or fewer carbon atoms.

In another embodiment of the second aspect, the organosilane coupling agent treated surface includes an aminosilane. In a specific embodiment, the aminosilane includes 3-aminopropyltrimethoxysilane, 3-aminopropyltriethoxysilane, N,N′-bis[(3-trimethoxysilyl)propyl]ethylenediamine, N-(2-aminoethyl)-3-aminopropyltrimethoxysilane, N-2-(vinylbenxzylamino)-ethyl-aminopropyltrimethoxysilane) or mixtures thereof.

In still another embodiment of the second aspect, the encapsulant layer includes a polymeric material selected from the group consisting of acid copolymers, ionomers of acid copolymers, ethylene-vinyl acetate copolymers, poly(vinyl acetals), polyurethanes, polyvinylchlorides, polyethylenes, polyolefin block elastomers, copolymers of α-olefins and α,β-ethylenically unsaturated carboxylic acid esters, silicone elastomers, epoxy resins, and combinations of two or more thereof. In a specific embodiment, the encapsulant layer includes an ethylene-vinyl acetate copolymer.

In yet another embodiment of the second aspect, the encapsulant layer further includes an organosilane coupling agent that may be the same or different than the coupling agent used to provide the treated surface of the tetrafluoroethylene-hexafluoropropylene copolymer film.

In still yet another embodiment of the second aspect, an integrated frontsheet for a photovoltaic module includes the weatherable multilayer film. In a more specific embodiment, a photovoltaic module includes the integrated frontsheet.

In a third aspect, a photovoltaic module includes a frontsheet, a front encapsulant layer, a cell layer, and a backsheet. The frontsheet includes a transparent film including a tetrafluoroethylene-hexafluoropropylene copolymer layer having an organosilane coupling agent treated surface. The front encapsulant layer is directly laminated to the treated surface of the frontsheet. An average peel strength between the frontsheet and the encapsulant layer is greater than 2 lbf/in after 1000 hrs of damp heat exposure.

Many aspects and embodiments have been described above and are merely exemplary and not limiting. After reading this specification, skilled artisans appreciate that other aspects and embodiments are possible without departing from the scope of the invention. Other features and advantages of the invention will be apparent from the following detailed description, and from the claims.

A transparent film having a tetrafluoroethylene-hexafluoropropylene (FEP) layer with an organosilane coupling agent treated surface can be directly laminated to an encapsulant layer via the organosilane coupling agent treated surface to form a weatherable multilayer film that may be used as an integrated frontsheet for a photovoltaic module. A weatherable multilayer film is a film in which the individual layers are durably adhered to each other, such that the peel strength between the layers is greater than 2 lbf/in after 1000 hours of damp heat exposure as described in the test methods below. In one embodiment, where the encapsulant layer includes an ethylene-vinyl acetate copolymer, the multilayer film is cured at a sufficient temperature for a time sufficient to crosslink the ethylene-vinyl acetate copolymer prior to the 1000 hours of damp heat exposure. An integrated frontsheet is a film that can provide the necessary barrier properties to protect the electrical components of a photovoltaic module and can be durably adhered to the solar cell layer of the module.

In one embodiment, an integrated frontsheet can include a transparent film layer and an encapsulant layer directly laminated to the transparent film layer. As used herein, the term “directly laminated” means that two or more layers have been attached to each other using a lamination process incorporating heat and/or pressure with no additional intervening layers. Examples of direct lamination processes include extrusion coating, nip lamination, etc., and are described in greater detail below. Between two directly laminated layers, although one or both layers may have previously undergone a surface treatment that modifies the adhesion characteristics of the layer(s), no additional layers of adhesives or coatings are incorporated during the lamination process. For example, a fluoropolymer film may undergo a surface treatment that introduces an organosilane coupling agent to the fluoropolymer film surface which improves the adhesion of the fluoropolymer film when it is directly laminated to an encapsulant layer.

In some embodiments, direct lamination may be used to form a multilayer film suitable for storage, transportation and handling. The multilayer film can include an encapsulant layer and a transparent film layer having a treated surface, wherein the two layers are attached to each other via the treated surface. The adhesion of the two layers may be adequate for storage, transportation and handling. Subsequent processing may be used to durably adhere the encapsulant layer to the treated surface of the transparent film, forming a weatherable multilayer film. In a specific embodiment, the process of durably adhering the layers together may be performed when the multilayer film is assembled in contact with a cell layer in the process of forming a PV module.

In one embodiment, to durably adhere a transparent film layer to an encapsulant layer, a vacuum laminator may be used and heat and/or pressure can be applied in such a manner that if the encapsulant included a formulated EVA copolymer, as described below, the EVA copolymer would melt and crosslink to a gel content of at least 65%. In one embodiment, a uniform pressure of 999 mbar may be applied to the outer surfaces of the multilayer film to press the encapsulant in contact with the treated surface of the transparent film while heating the multilayer such that the encapsulant reaches a temperature of at least 140° C. but not more than 150° C. for at least 5 minutes, but not more than 10 minutes.

### Tetrafluoroethylene-Hexafluoropropylene Copolymer (FEP) Films

Tetrafluoroethylene-Hexafluoropropylene (FEP) copolymers may be used to form transparent films. By the term “FEP copolymers” is meant comonomers of tetrafluoroethylene (TFE) and hexafluoropropylene (HFP) with any number of additional monomer units so as to form dipolymers, terpolymers, tetrapolymers, etc. If nonfluorinated monomers are used, the amount used should be limited so that the copolymer retains the desirable properties of the fluoropolymer, i.e., weather resistance, solvent resistance, barrier properties, etc. In one embodiment, fluorinated comonomers include fluoroolefins and fluorinated vinyl ethers.

In FEP copolymers, the HFP content is typically about 6-17 wt %, preferably 9-17 wt % (calculated from HFPI×3.2). HFPI (HFP Index) is the ratio of infrared radiation (IR) absorbances at specified IR wavelengths as disclosed in U.S. Statutory Invention Registration H130. In one embodiment, FEP copolymers can include a small amount of additional comonomer to improve properties. The FEP copolymer can be TFE/HFP/perfluoro(alkyl vinyl ether) (PAVE), wherein the alkyl group contains 1 to 4 carbon atoms. PAVE monomers can include perfluoro(ethyl vinyl ether) (PEVE) and perfluoro(propyl vinyl ether) (PPVE). In one embodiment, FEP copolymers containing the additional comonomer have an HFP content of about 6-17 wt %, preferably 9-17 wt % and PAVE content, preferably PEVE, of about 0.2 to 3 wt %, with the remainder of the copolymer being TFE to total 100 wt % of the copolymer.

Examples of FEP compositions are those disclosed in U.S. Pat. Nos. 4,029,868 (Carlson), 5,677,404 (Blair), and 6,541,588 (Kaulbach et al.) and in U.S. Statutory Invention Registration H130. The FEP may be partially crystalline, that is, it is not an elastomer. By partially crystalline is meant that the polymers have some crystallinity and are characterized by a detectable melting point measured according to ASTM D 3418, and a melting endotherm of at least about 3 J/g.

In one embodiment, the FEP copolymers may be terpolymers containing less than 10 wt % HFP (about 6 to 10 wt %), less than 2 wt % of perfluoroethylvinylether PEVE (about 1.5 to 2 wt %), and with the remainder TFE. An example copolymer has 7.2 to 8.1 wt % of HFP, 1.5 to 1.8 wt % of PEVE and 90.1 to 91.3 wt % of TFE, with a nominal melt flow rate (MFR) of 6 to 8 g/10 min as defined in ASTM D2116 and a melting point in the range of 260 to 270° C.

FEP transparent films may be formed by any technique known to those skilled in the art. For example, the films may be extrusion cast and optionally stretched and heat stabilized. The FEP film may be oriented to provide improved properties, such as improved toughness and tensile strength.

The FEP transparent film can have a thickness in the range of about 10 to 200 microns, or about 25 to 150 microns, or about 50 to 125 microns and a transmission of greater than about 90%, or greater than about 94%, or greater than about 97% in the visible region of the electromagnetic spectrum.

In one embodiment, the FEP transparent film undergoes an initial surface treatment prior to a surface treatment with an organosilane coupling agent. This initial surface treatment may take any form known within the art and includes flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments (see, e.g., U.S. Pat. Nos. 3,030,290; 3,676,181; and 6,726,979), chemical treatments, chromic acid treatments, hot air treatments, ozone treatments, ultraviolet light treatments, sand blast treatments, solvent treatments, and combinations of two or more thereof, or multiple applications of the same treatment. Plasma or corona treatment can include reactive hydrocarbon vapors such as ketones, e.g., acetone, alcohols, p-chlorostyrene, acrylonitrile, propylene diamine, anhydrous ammonia, styrene sulfonic acid, carbon tetrachloride, tetraethylene pentamine, cyclohexyl amine, tetra isopropyl titanate, decyl amine, tetrahydrofuran, diethylene triamine, tertiary butyl amine, ethylene diamine, toluene-2,4-diisocyanate, glycidyl methacrylate, triethylene tetramine, hexane, triethyl amine, methyl alcohol, vinyl acetate, methylisopropyl amine, vinyl butyl ether, methyl methacrylate, 2-vinyl pyrrolidone, methylvinylketone, xylene or mixtures thereof. This initial surface treatment further enhances the adhesion of the FEP film to the encapsulant layer.

FEP films commercially available from E. I. du Pont de Nemours and Company (DuPont), Wilmington, Del., under the Teflon® tradename with the “Type C” designation, such as the grade FEP-500C, are suitable for use in this invention.

### Organosilane Coupling Agents

The FEP transparent film is surface treated with an organosilane coupling agent. The organosilane coupling agent improves the adhesion of the FEP film to the encapsulant layer when forming multilayer films. A silane coupling agent is a silicon-based compound that contains two types of reactivity, inorganic and organic, in the same molecule. Silane coupling agents typically act as an interface between an inorganic substrate (e.g., ceramic, glass, metal) and an organic layer (e.g., an organic polymer or coating) to bond the two dissimilar materials. For example, when an organic polymer is reinforced with an inorganic filler, a silane coupling agent may be used to ensure good adhesion between the inorganic filler and the organic polymer, providing a stable bond between two otherwise poorly bonding surfaces.

An organosilane coupling agent is a silane coupling agent that contains at least one carbon atom. Typically, a silicon atom is bonded to three hydrolysable groups, such as methoxy-, ethoxy-, chloro-, or acetoxy- and an organoreactive group. When used as a coupling agent, the silicon atom is typically bonded to an inorganic substrate via the hydrolysable groups and then either reacts with or physically entangles with a polymer or other organic material via the organoreactive group. Surprisingly, it is found that organosilane coupling agents are useful to improve the adhesion of FEP transparent films to encapsulant layers to form weatherable multilayer films.

Organosilane coupling agents can be prepared with a wide variety of organoreactive groups. Some example of different types of organoreactive groups of organosilane coupling agents can include amino, benzylamino, methacrylate, vinylbenzylamino, epoxy, chloro, melamine, vinyl, ureido, mercapto, disulfide, and tetrasulfido groups. An organosilane coupling agent can include a single type of organoreactive group, a mixture of two or more groups of the same type, a mixture of two or more different types of groups, or a combination thereof. In one particular embodiment, the organosilane coupling agent is an aminosilane having at least one amine functional group. Examples of aminosilanes include 3-aminopropyltrimethoxysilane (APTMS), 3-aminopropyltriethoxysilane (APTES), N,N′-bis[(3-trimethoxysilyl)propyl]ethylenediamine (dipodalAP), N-(2-aminoethyl)-3-aminopropyltrimethoxysilane (AEAPTMS), and N-2-(vinylbenzylamino)-ethyl-aminopropyltrimethoxysilane) (SMAEAPTMS).

Organosilane coupling agents have been used in the past to improve adhesion between compositions used as encapsulant materials and various materials used in incident layers of photovoltaic modules. For example, ethylene-vinyl acetate (EVA) copolymer compositions used in photovoltaic module encapsulant layers generally include an organosilane coupling agent such as 3-methacryloxypropyltrimethoxysilane to facilitate bonding to other materials. See “Adhesion Strength Study of EVA Encapsulants on Glass Substrates” F. J. Pern and S. H. Glick, NCPV and Solar Program Review Meeting 2003 NREL/CD-520-33586, page 942.

However, previous organosilane-modified encapsulants have not provided sufficient adhesion to perfluorinated copolymer resins such as FEP to provide robust photovoltaic cells. Furthermore, some organosilane coupling agents, such as certain aminosilane coupling agents cannot be mixed into, i.e. incorporated into, ethylene α-β-unsaturated carboxylic acid copolymers and ionomer encapsulant materials because the resulting compositions have unacceptable levels of gel formation when formed into films.

Surprisingly however, it has been found that organosilane coupling agents are useful as a surface treatment to improve the adhesion of FEP transparent films to encapsulant layers, including such encapsulant layer materials as ethylene acid copolymers, ionomers, ethylene alkyl acrylate copolymers, ethylene alkyl methacrylate copolymers and ethylene vinyl acetate copolymers.

The organosilane coupling agent can include a single organosilane, or a combination of two or more organosilanes. The organosilane coupling agent may be applied using any known technique including liquid phase (e.g., dip coating, spray coating, etc.) and gas phase (e.g., vapor deposition) techniques. In one embodiment, the organosilane coupling agent is applied as a liquid solution, generally a solution wherein the concentration of organosilane is from 0.01 to 10% by weight. In a more specific embodiment, the concentration of organosilane is from 0.05 to 1% by weight. In a still more specific embodiment, the concentration of organosilane is from 0.05 to 0.5% by weight. The organosilane may be dissolved in a solution including a polar organic solvent and applied to the FEP transparent film using a dip coating technique, followed by drying to remove the solvent. The drying may occur at an elevated temperature, sufficient to drive off the liquid solvent. The polar organic solvent may be a low molecular weight alcohol, such as those having 8 or fewer, preferably 4 or fewer, carbon atoms, (e.g., methanol, ethanol, propanol, or isopropanol). In one embodiment, the solution may include a mixture of a polar organic solvent and water. In a specific embodiment, the solution may include a mixture in the range of 25 to 95% (by volume) of polar organic solvent in water. For example, a 0.1 wt % organosilane solution may be applied using a solvent of 95% (by volume) ethanol in water, and then dried at 100° C. In another example, a solvent of 25% (by volume) of n-propanol in water may be used. Skilled artisan will appreciate that a range of solution compositions and drying temperatures can be used, and that the composition and drying temperature will depend on the particular organosilane in combination with the solvent chosen, as well as the surface characteristics of the FEP film and the encapsulant layer to which the transparent film will be adhered.

Although the entire surface area of the FEP transparent film may be treated, the surface treatment need not provide a contiguous and/or uniform coating of organosilane on the surface of the film, but sufficient organosilane should be applied in order to significantly increase adhesion to an encapsulant layer. Too much organosilane coupling agent may not provide increased adhesion between the FEP transparent film and the encapsulant layer because the organosilane may self-condense to form a weak, brittle siloxane network on the surface of the film. This siloxane network can fail cohesively, resulting in interlayer separation.

In one embodiment, when using solution coating techniques, the concentration of organosilane in the solution is from about 0.01 to 1 wt %, and in a more particular embodiment from about 0.05 to 0.5 wt %.

The FEP transparent film having an organosilane coupling agent treated surface can have a thickness in the range of about 10 to 200 microns, or about 25 to 150 microns, or about 50 to 125 microns and a transmission of greater than about 90%, or greater than about 94%, or greater than about 97% in the visible region of the electromagnetic spectrum, defined as light having wavelengths between about 380 to about 780 nm. High transparency may also be observed in regions of the electromagnetic spectrum beyond the visible region such as between about 350 to about 800 nm or higher, or about 350 to 1200 nm.

### Encapsulant Materials

An encapsulant layer may comprise a polymeric material selected from the group consisting of acid copolymers, ionomers of acid copolymers, ethylene-vinyl acetate copolymers, poly(vinyl acetals) (including acoustic grade poly(vinyl acetals)), polyurethanes, polyvinylchlorides, polyethylenes (e.g., linear low density polyethylenes), polyolefin block elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof.

In one embodiment, the composition of the encapsulant layer may comprise an ethylene-vinyl acetate (EVA) copolymer comprising copolymerized units of ethylene and vinyl acetate. These copolymers may comprise 25 to 35, preferably 28 to 33, weight % of vinyl acetate. The ethylene-vinyl acetate copolymer may have a melt flow rate (MFR) of about 0.1 to about 1000 g/10 minutes, or about 0.3 to about 30 g/10 minutes, as determined in accordance with ASTM D1238 at 190° C. and 2.16 kg.

The ethylene-vinyl acetate copolymer used in the encapsulant layer composition may be in the form of a single ethylene-vinyl acetate copolymer or a mixture of two or more different ethylene-vinyl acetate copolymers. By different ethylene-vinyl acetate copolymers is meant that the copolymers have different comonomer ratios. They may also be copolymers that have the same comonomer ratios, but different MFR due to having different molecular weight distributions.

Ethylene-vinyl acetate copolymers useful herein include those available from DuPont under the tradename Elvax®.

In one embodiment, the encapsulant layer comprises a thermoplastic polymer selected from the group consisting of acid copolymers, ionomers of acid copolymers, and combinations thereof (i.e. a combination of two or more acid copolymers, a combination of two or more ionomers of acid copolymers, or a combination of at least one acid copolymer with one or more ionomers of acid copolymers). In particular, the acid copolymers used herein may be copolymers of an α-olefin having 2 to 10 carbons and an α,β-ethylenically unsaturated carboxylic acid having 3 to 8 carbons. For example, the acid copolymer may comprise about 15 to about 30 wt % of copolymerized units of the α,β-ethylenically unsaturated carboxylic acid, based on the total weight of the copolymer.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and combinations of two or more of such comonomers. In one embodiment, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and combinations of two or more thereof. In one embodiment, the α,β-ethylenically unsaturated carboxylic acid is selected from the group consisting of acrylic acids, methacrylic acids, and combinations of two or more thereof.

The acid copolymers may further comprise copolymerized units of other comonomer(s), such as unsaturated carboxylic acids having 2 to 10, or preferably 3 to 8 carbons, or derivatives thereof. Suitable acid derivatives include acid anhydrides, amides, and esters. In one embodiment, the acid derivatives used are esters. Specific examples of esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, dimethyl maleates, diethyl maleates, dibutyl maleates, dimethyl fumarates, diethyl fumarates, dibutyl fumarates, dimethyl fumarates, vinyl acetates, vinyl propionates, and combinations of two or more thereof. In certain embodiments, acid copolymers used here may not comprise comonomers other than the α-olefins and the α,β-ethylenically unsaturated carboxylic acids.

Acid copolymers useful herein include those available from DuPont under the tradename Nucrel®.

The ionomers of acid copolymers useful as components of the encapsulant layers are ionic, neutralized derivatives of precursor acid copolymers, such as those acid copolymers disclosed above. In one embodiment, the ionomers of acid copolymers are produced by neutralizing the acid groups of the precursor acid copolymers with a reactant that is a source of metal ions in an amount such that neutralization of about 10% to about 60%, or about 20% to about 55%, or about 35% to about 50% of the carboxylic acid groups takes place, based on the total carboxylic acid content of the precursor acid copolymers as calculated or measured for the non-neutralized precursor acid copolymers. Neutralization may often be accomplished by reaction of the precursor acid polymer with a base, such as sodium hydroxide, potassium hydroxide, or zinc hydroxide.

The metal ions may be monovalent ions, divalent ions, trivalent ions, multivalent ions, or combinations of two or more thereof. Useful monovalent metallic ions include, but are not limited to sodium, potassium, lithium, silver, mercury, and copper. Useful divalent metallic ions include, but are not limited to beryllium, magnesium, calcium, strontium, barium, copper, cadmium, mercury, tin, lead, iron, cobalt, nickel, and zinc. Useful trivalent metallic ions include, but are not limited to, aluminum, scandium, iron, and yttrium. Useful multivalent metallic ions include, but are not limited, to titanium, zirconium, hafnium, vanadium, tantalum, tungsten, chromium, cerium, and iron. It is noted that when the metallic ion is multivalent, complexing agents such as stearate, oleate, salicylate, and phenolate radicals may be included, as disclosed in U.S. Pat. No. 3,404,134. In one embodiment, the metal ions are monovalent or divalent metal ions. In a further embodiment, the metal ions are selected from the group consisting of sodium, lithium, magnesium, zinc, potassium and combinations of two or more thereof. In a yet further embodiment, the metal ions are selected from sodium, zinc, and combinations thereof. In a yet further embodiment, the metal ion is sodium.

Ionomer resins useful herein include those available from DuPont under the tradename Surlyn®. Ionomer encapsulant sheets are available from DuPont in the PV5000 series of encapsulant sheets.

Alternatively, the encapsulant layer may comprise an ethylene/alkyl acrylate copolymer comprising copolymerized units of ethylene and an alkyl acrylate. The alkyl moiety of the alkyl acrylate may contain 1 to 6 or 1 to 4 carbon atoms, such as methyl, ethyl, and branched or unbranched propyl, butyl, pentyl, and hexyl groups. Exemplary alkyl acrylates include, but are not limited to, methyl acrylate, ethyl acrylate, iso-butyl acrylate, and n-butyl acrylate. The polarity of the alkyl acrylate comonomer may be manipulated by changing the relative amount and identity of the alkyl group present in the comonomer. Similarly, a C₁-C₆ alkyl methacrylate comonomer may be used as a comonomer. Such comonomers include methyl methacrylate, ethyl methacrylate, i-butyl methacrylate, and n-butyl methacrylate.

These copolymers may comprise 20 to 40, preferably 24 to 35, weight % of alkyl acrylate.

The ethylene/alkyl acrylate copolymers and ethylene/alkyl methacrylate copolymers useful herein may have melt flow rates ranging from about 0.1 to about 200 g/10 minutes, as determined in accordance with ASTM D1238 at 190° C. and 2.16 kg, and therefore suitable ethylene/alkyl acrylate copolymers and ethylene/alkyl methacrylate copolymers can vary significantly in molecular weight.

The copolymer used in the encapsulant layer composition may be in the form of a single ethylene/alkyl acrylate copolymer, a single alkyl methacrylate copolymer, or a mixture of any two or more different ethylene/alkyl acrylate copolymers and/or ethylene alkyl methacrylate copolymers. Blends of at least one ethylene/alkyl acrylate copolymer and at least one ethylene/alkyl methacrylate copolymer are also contemplated as useful in the practice of the invention.

The ethylene/alkyl acrylate copolymers and/or ethylene/alkyl methacrylate copolymers may be prepared by processes well known in the polymer art using either autoclave or tubular reactors. For example, the copolymerization can be conducted as a continuous process in an autoclave, where ethylene, the alkyl acrylate (or alkyl methacrylate), and optionally a solvent such as methanol (see U.S. Pat. No. 5,028,674) are fed continuously into a stirred autoclave such as the type disclosed in U.S. Pat. No. 2,897,183, together with an initiator. Alternatively, the ethylene/alkyl acrylate copolymer (or ethylene/alkyl methacrylate copolymer) may be prepared in a tubular reactor, according to the procedure described in the article “High Flexibility EMA Made from High Pressure Tubular Process” (Annual Technical Conference—Society of Plastics Engineers (2002), 60th (Vol. 2), 1832-1836). The ethylene/alkyl acrylate copolymer (or ethylene/alkyl methacrylate copolymer) also may be obtained in a high pressure, tubular reactor at elevated temperature with additional introduction of reactant comonomer along the tube. The ethylene/alkyl acrylate copolymer or ethylene/alkyl methacrylate copolymer also may be produced in a series of autoclave reactors wherein comonomer replacement is achieved by multiple zone introduction of reactant comonomer as taught in U.S. Pat. Nos. 3,350,372; 3,756,996; and 5,532,066.

Ethylene/alkyl acrylate copolymers useful herein include those available from DuPont under the tradename Elvaloy® AC.

The encapsulant layer composition may further contain one or more additives, such as processing aids, flow enhancing additives, lubricants, pigments, dyes, flame retardants, impact modifiers, nucleating agents, anti-blocking agents such as silica, thermal stabilizers, UV absorbers, UV stabilizers, hindered amine light stabilizers (HALS), silane coupling agents, dispersants, surfactants, chelating agents, coupling agents, reinforcement additives (e.g., glass fiber), and fillers. Ethylene-vinyl acetate copolymer compositions also frequently contain crosslinking agents such as organic peroxides.

An organosilane coupling agent can be incorporated into an encapsulant composition by a variety of techniques including melt blending or imbibing. EVA copolymer compositions used in photovoltaic module encapsulant layers generally include an organosilane coupling agent such as 3-methacryloxypropyltrimethoxysilane to facilitate bonding to other materials. However, EVA compositions containing such organosilane coupling agents do not have sufficient adhesion to untreated FEP films to allow for the use of these untreated FEP films in photovoltaic modules. Aminosilane coupling agents are not usually incorporated into compositions comprising ethylene acid copolymers or ionomers of ethylene acid copolymers because films prepared therefrom may have unacceptable levels of gel formation.

Accordingly, the composition comprising the encapsulant layer may further comprise an organosilane coupling agent, provided that when the composition of either layer comprises an ethylene acid copolymer or ionomer of an ethylene acid copolymer, the organosilane coupling agent does not comprise an aminosilane. A silane coupling agent in the encapsulant layer may be the same or different than the organosilane coupling agent used to treat the surface of a transparent FEP film.

Encapsulant layers may be positioned between the solar cell layer and the incident layer, between the solar cell layer and the backing layer, or both. The total thickness of each of the encapsulant layers may be in the range of about 0.026 to about 3 mm, or about 0.25 to about 2.3 mm, or about 0.38 to about 1.5 mm, or about 0.51 to about 1.1 mm.

### Multilayer Films

The FEP transparent film having an organosilane coupling agent treated surface can be directly laminated to an encapsulant layer to form a multilayer film suitable for use as an integrated frontsheet for a photovoltaic module. In one embodiment, an encapsulant layer including a formulated, uncrosslinked EVA copolymer can be durably adhered to an FEP transparent film via the organosilane coupling agent treated surface. The two layers may be durably adhered together using heat and pressure sufficient to initially melt the EVA copolymer and then cure (crosslink) it, forming a weatherable multilayer film.

In one embodiment, formulated EVA resin may be extrusion coated onto a surface of an FEP film that has been treated with an organosilane coupling agent, and subsequently cured using heat and pressure to crosslink the EVA copolymer and form a weatherable multilayer film. In a specific example of this embodiment, the EVA/FEP multilayer film may have an initial adhesion adequate for storage, transportation and handling after extrusion coating. The multilayer film may be subject to additional heat and pressure during the module lamination process to form a weatherable multilayer film.

In one embodiment, an extrusion coating lamination process may be used to form a multilayer film. In a particular embodiment, polymer pellets, e.g. 28 to 32% vinyl acetate content EVA, may be fed into an extruder. Formulated compounds can be used and may be fully compounded, a combination of polymer pellets and pellets of a compounded concentrate, or a combination of polymer pellets and additives directly fed into the extruder. In a specific embodiment, for an extrusion coated directly laminated encapsulant layer containing EVA copolymer, compounded concentrates may be used. The feed zone of the extruder is kept cold enough to prevent premature melting or blocking in the feed zone. In one embodiment, melt temperatures for formulated EVA copolymer are below 140° C., and in a more particular embodiment below 100° C.

The polymer melt can be extruded through a flat die and directly laminated to a polymer film in a nip with two chilled rolls. A three roll stack may be used, but extrusion coated laminates can also be produced by extruding a molten polymer film or sheet onto a polymer film without the use of a nip roll. In one embodiment, for film containing EVA copolymer, a nip roll that is heavily textured on the air side of the film may be used. The texturing of the nip roll facilitates film quality evaluation during subsequent vacuum lamination and minimizes the risk of entrapping bubbles.

In another embodiment, a nip lamination process may be used to form a multilayer film. For example, an EVA containing encapsulant film that has been manufactured as described above but has not been directly laminated during the casting operation can be subsequently directly laminated to a polymer film in a secondary operation. In one embodiment, an EVA containing encapsulant film and an FEP transparent film are fed, from independent unwinds, into a nip between two rolls. The roll on the side of the FEP film may be heated to a temperature above 35° C. and the roll on the EVA side may be chilled to prevent sticking of the encapsulant film to the roll. Multiple combinations of configurations and textures can be used to create a multilayer film that will subsequently be exposed to an additional process comprising the application of heat and pressure, such as the vacuum lamination process used during the manufacture of photovoltaic modules.

### Photovoltaic Modules

Monocrystalline silicon (c-Si), poly- or multi-crystalline silicon (poly-Si or mc-Si) and ribbon silicon are the materials used most commonly in forming the more traditional wafer-based solar cells. Photovoltaic modules derived from wafer-based solar cells often comprise a series of self-supporting wafers (or cells) that are soldered together. The wafers generally have a thickness of between about 180 and about 240 μm.

Thin film solar cells are commonly formed from materials that include amorphous silicon (a-Si), microcrystalline silicon (μc-Si), cadmium telluride (CdTe), copper indium selenide (CuInSe₂ or CIS), copper indium sulfide, copper indium/gallium diselenide (CuInₓGa₍₁₋ₓ₎Se₂ or CIGS), copper indium/gallium disulfide, light absorbing dyes, and organic semiconductors. Thin film solar cells with a typical thickness of less than 2 μm are produced by depositing the semiconductor layers onto a superstrate or substrate formed of glass or a flexible film.

Photovoltaic modules useful in the invention include, but are not limited to, wafer-based solar modules (e.g., c-Si or mc-Si based solar cells) and thin film solar modules (e.g., a-Si, μc-Si, CdTe, CIS, CIGS, light absorbing dyes, or organic semiconductors based solar cells). Within the solar cell layer, the solar cells may be electrically interconnected and/or arranged in a flat plane. In addition, the solar cell layer may further comprise electrical wirings, such as cross ribbons and bus bars.

In a typical module construction, the solar cell layer is sandwiched between two encapsulant layers, which are further sandwiched between the frontsheet and backsheet layers, providing weather resistance, UV resistance, moisture barrier properties, low dielectric constant, and high break down voltage. In some embodiments, suitable backsheet layers comprise polymers that include but are not limited to, polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, and ethylene-tetrafluoroethylene copolymers), and combinations of two or more thereof. The polymeric film may be non-oriented, or uniaxially oriented, or biaxially oriented. In one embodiment, a multilayer film of polyester (PET) sandwiched between two layers of polyvinyl fluoride (PVF) is commonly used as a backsheet for PV modules. In some embodiments backsheet layers may comprise glass, metal, ceramic, or other materials and combinations thereof. In other embodiments, a module may be adhered to an article (e.g., a building, a vehicle, a device, etc.) where the article itself acts as a backsheet. A wide variety of materials may be used for the backsheet, as long as the necessary barrier properties needed (e.g., strength, weather resistance, UV resistance, moisture barrier properties, low dielectric constant, high break down voltage, etc.) to protect the module from degradation of cell performance are provided.

In one embodiment, a bifacial module receives incident light from both sides of the device, incorporating a transparent layer on both front and back. In a more particular embodiment, an FEP transparent film may be used on one side of a bifacial device, while a glass layer is used as a transparent layer on a second side. In another more particular embodiment for a flexible bifacial module, FEP transparent layers may be used on both sides of the device. Alternatively, an FEP transparent layer may be used as a transparent layer on one side of the device with an ETFE transparent layer used on the other side of the device.

The solar cell module may further comprise other functional film or sheet layers (e.g., dielectric layers or barrier layers) embedded within the module. For example, poly(ethylene terephthalate) films coated with a metal oxide coating, such as those disclosed within U.S. Pat. Nos. 6,521,825 and 6,818,819 and European Patent No. EP1182710, may function as oxygen and moisture barrier layers in PV modules.

If desired, a layer of fiber (scrim) may also be included between the solar cell layers and the encapsulants to facilitate deaeration during the lamination process or to serve as reinforcement for the encapsulants. The fiber may be a woven or nonwoven glass fiber or a networked mat of connected fibers. The use of such scrim layers is disclosed within, e.g., U.S. Pat. Nos. 5,583,057; 6,075,202; 6,204,443; 6,320,115; and 6,323,416 and European Patent No. EP0769818.

### EXAMPLES

The concepts described herein will be further described in the following examples, which do not limit the scope of the invention described in the claims.

### Lamination Method

A vacuum laminator is used to fabricate laminates for weathering and adhesion testing. The laminator comprises a platen base, on which the sample rests during lamination. The laminator also comprises an enclosure that covers and completely surrounds the platen base and sample. The region enclosed by the platen and enclosure may be evacuated. The laminator also comprises a flexible rubber bladder within the enclosure. The bladder is attached to the top inner surface of the enclosure and may be inflated to a pressure greater than the pressure in the evacuated region. When the bladder is inflated, the flexible surface of the bladder is pushed from the top of the enclosure toward the platen and applies a surface pressure to the sample. This ensures a good thermal contact between the sample and the platen.

Samples comprise a glass substrate, a formulated EVA sheet, and a flexible top sheet. The glass may be 3 mm thick low iron float glass, e.g., Krystal Klear® (available from AFG Industries, Kingsport, Tenn.) or Diamant® (available from Saint Gobain Glass, Scottsdale, Ariz.).

A formulated EVA sheet can be made using the composition in Table 1. EVA resin pellets can be blended with a formulated concentrate containing peroxide, UV stabilizers and silane in an EVA resin matrix and fed to a single screw extruder, where it is melt-extruded, filtered and fed to a sheet die maintained at elevated temperature. The polymer can then be extruded through the die and fed to a nip formed between a matt-finished steel roll and a roughened rubber roll to impart a cross-hatched surface pattern to the sheet. The sheet can then be cooled and collected on a roll winder. Alternatively, a formulated EVA film, such as Bixcure® EVA (available from Bixby International, Newburyport, Mass.) 0.018 inch thick may be used.

TABLE 1

| Compound | Parts | Form | Supplier |
|---|---|---|---|
| Elvax ® 150 | 100 | Pellets | DuPont |
| Lupersol ® TBEC | 1.5 | Liquid | Arkema |
| Cyasorb ® UV-531 | 0.3 | Liquid | Cytec |
| Naugard ® P | 0.2 | Liquid | Chemtura |
| Tinuvin ® 770 | 0.1 | Powder | Ciba-Geigy |
| 3-methacryloxypropyl- | 0.25 | Powder | Dow-Corning |
| trimethoxysilane | | | |

The flexible top sheet can be an FEP film, such as an FEP film treated with a silane solution, e.g., cementable, 5 mil Teflon® FEP-500C film (available from DuPont). The cementable side, or silane treated cementable side, of the FEP film is placed in contact with the EVA film, such that the EVA film is sandwiched between the glass and the FEP film. The size of the laminated area of the samples can be 4 inches by 4 inches, with the entire FEP film measuring 4 inches by 7 inches. The additional 3 inches can be made to overhang on one side of the sample and are not laminated to anything.

The object of the lamination process is to first melt the EVA so that it makes intimate conformal contact with both the glass surface below it and FEP surface above it and then to cure (crosslink) the EVA. Crosslinking is achieved by maintaining the EVA for a sufficient time at a sufficiently high temperature. The interface between FEP and EVA and between glass and EVA should be free of voids, defects, and air pockets.

The sample may be assembled at room temperature. After assembling the sample, it may be placed on top of several heat resistant layers. The heat resistant layers slow the heating rate of the EVA so that it does not crosslink quickly and trap air pockets and other defects before all the air can escape from the interfaces. The heat resistant layers may be 2-4 layers of Sontara® Z-11 spunlaced fabric (1.8-2.0 oz./yard, available from DuPont Advanced Fiber Systems, Wilmington, Del.) and a layer of 10 mil thick FEP. Another layer of 10 mil thick FEP is placed on top of the sample to prevent any EVA that flows out of the sample from adhering to parts of the laminator. Both the underlying heat resistant layers and overlying FEP layer may be much larger in area than the sample.

The assembled overlying FEP film, sample, and heat resistant layers are then placed onto the platen, which is preheated to a temperature of 150° C. Immediately after placing the assembly on the platen, the enclosure of the laminator is lowered into place and sealed. Next, the region surrounding the sample between the platen and enclosure of the laminator is evacuated to a pressure of 1 mbar to help further with the prevention of voids, defects, and air pockets. The evacuation step takes four minutes, and the platen is maintained at 150° C. during this step. Next, the rubber bladder is inflated to a pressure of 999 mbar so that it presses against the sample and other layers and ensures good thermal contact with the platen. The pressurization step takes one minute, and the platen is maintained at 150° C. during this step. In the next step, the enclosure pressure (1 mbar), bladder pressure (999 mbar), and the temperature of the platen (150° C.) are held constant for 13 to 20 minutes, depending on the number of heat resistant layers. The time is chosen such that the internal temperature of the EVA reaches 140° C. for at least 5 minutes. This time and temperature allows for sufficient crosslinking to occur (e.g., a gel content of at least 65%). The internal temperature of the EVA is measured by placing a thermocouple sensor between the EVA and glass during the assembly of a witness sample and then monitoring the temperature during the lamination process. As the EVA melts, the thermocouple is completely surrounded by the EVA. When the crosslinking step is complete, the bladder is depressurized to 0 mbar so that it is removed from contact with the sample and other layers. The depressurization step takes thirty seconds, and the platen is maintained at 150° C. during this step. Next, the enclosure is vented to atmospheric pressure and the enclosure is unsealed and opened. The opening step takes thirty seconds, and the platen is maintained at 150° C. during this step. The samples and other layers then are immediately removed from the platen and allowed to cool at room temperature for at least 10 minutes.

An alternative to this process includes two additional layers above the sample during the lamination process. The layers are an additional layer of 10 mil thick FEP and a 3 mm thick piece of glass, arranged above the sample, so that the upper layer of glass is sandwiched between the two 10 mil thick layers of FEP. This arrangement may be used if defects are observed in one of the other arrangements, because the additional layers further slow the heating rate. In this case, the cross-linking step may last 20 to 30 minutes rather than 13 to 20 minutes.

The lamination methodology mentioned here is by no means the only possible way to carry out the lamination. For example, more advanced laminators have retractable pins that hold the sample above the heat source until the desired time to effect contact and heating. This would obviate the need for the heat resistant layers in most cases. The method described here is the one used when fabricating the samples described in the examples of this patent.

### Test Methods

### Damp Heat Exposure

Laminated samples are placed into a dark chamber, with the glass substrate resting on a support. The sample is preferably mounted at approximately a 45 degree angle to the horizontal. The chamber is then brought to a temperature of 85° C. and relative humidity of 85%. These conditions are maintained for a specified number of hours. Samples are typically removed and tested after an exposure of 1000 hours, because 1000 hours at 85° C. and 85% relative humidity is the required exposure in many photovoltaic module qualification standards.

### Peel Test Method

Peel strength is a measure of adhesion of laminated samples. To prepare for the peel strength test, a blade is passed through the FEP top sheet and EVA layers of the laminate sequentially to create parallel cuts separated by a known distance (one inch in the experimental results discussed here). The one inch sections of the sample are parallel to the longest dimension of the FEP top sheet and the cuts also continue from the laminated region through the three inch section of the FEP that is not laminated to anything. The sections are arranged so as to be interior to the laminated region and not encroaching on the edge of the laminated region within a perimeter of 0.375 inch around the edge of the laminated region, except on the side adjacent to the three inch section of the FEP that is not laminated to anything. On that side, the sections continue directly from the laminated region to the non-laminated region of FEP.

In the peel strength test, the laminated sample is rigidly fixed into place. One of the one inch wide cut sections of the flexible FEP top sheet is then affixed to a movable member. The one inch wide section of the FEP is extended from a length of 3 inches by sandwiching it between two layers of aluminum foil coated with a pressure sensitive adhesive. The aluminum foil is then pressed between two grips attached to the movable member, so that the flexible FEP section is bent at an angle of 180° to the laminate, that is, the free flexible part of the FEP top sheet is bent until it just nearly makes contact with itself. Care is taken to align the free part of the section so that it overlaps the laminated part of the section. This geometry is based on ASTM D903, a standard test used for pressure sensitive adhesives.

In this 180° configuration, the movable member is then displaced at a constant velocity of 100 mm/min so that the FEP top sheet is placed into tension and is peeled from the glass and EVA layers, which remain fixed in place. Usually a large initial tension force is required to start the peel, and a constant steady-state force is needed to propagate the peel. When reporting results, the average force during the constant steady-state peel propagation is reported. Peel strength results are recorded only for clean peels when the FEP peels away from and leaves behind the EVA and glass layers. In cases when the FEP top sheet breaks before peeling occurs, or when the EVA layer remains adhered to the FEP top sheet and peels from the glass instead, no results are recorded.

### Examples 1 to 5 and Comparative Examples A to E

For Examples 1 to 5, different organosilane coupling agents (available from Sigma-Aldrich. St. Louis, Mo.) were used to treat the cementable surface of 5 mil Teflon® FEP-500C films. The films were then laminated to EVA films as described above to form 4×4 inch laminates. Each laminate was subjected to 1000 hours of damp heat exposure before testing peel strength as described above. Three or more laminates were made for each example, and up to three one inch width peel tests were performed for each laminate. The peel strengths reported in Table 2 represent a range for up to nine tests per example.

Comparative Example A did not receive any organosilane coupling agent surface treatment, only corona treatment of the FEP film surface. Comparative Examples B to E were prepared as described above for Examples 1 to 5.

TABLE 2

| | | Peel strength |
|---|---|---|
| Example | Silane | (lbf/in) |
| 1 | 3-aminopropyltrimethoxysilane | 6-13 |
| 2 | 3-acryloxypropyltrimethoxysilane | 2-3 |
| 3 | N,N′-bis[(3-trimethoxy- | 2-3 |
| | silyl)propyl]ethylenediamine | |
| 4 | N-(2-aminoethyl)-3-aminopropyl- | 2-5 |
| | trimethoxysilane | |
| 5 | N-2-(vinylbenzylamino)-ethylamino- | 2.5-3.5 |
| | propyltrimethoxysilane | |
| Comp. A | No silane treatment | 0.2-0.6 |
| Comp. B | Bis(triethoxysilyl)ethane | 0.4-0.9 |
| Comp. C | 3-glycidoxypropyltrimethoxysilane | 0.5-1.1 |
| Comp. D | 3-methacryloxypropyltrimethoxysilane | 0.6-0.9 |
| Comp. E | 3-mercaptopropyltrimethoxysilane | 0.9-1.0 |

Although the surface treatments using the organosilane coupling agents in Comparative Examples B to E did not result in peel strengths of greater than 2 lbf/in after 1000 hours of damp heat exposure, skilled artisans will appreciate that modifications of the processing conditions (e.g., coating composition, coating technique, coating conditions, prior surface treatments, lamination parameters etc.) could result in improved adhesion that may result in the formation of weatherable multilayer films.

Note that not all of the activities described above in the general description or the examples are required, that a portion of a specific activity may not be required, and one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof has been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all of the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any sub-combination. Further, reference to values stated in ranges include each and every value within that range.

What is claimed is:

1. A transparent film comprising a tetrafluoroethylene-hexafluoropropylene copolymer layer having an organosilane coupling agent treated surface such that said treated surface of said transparent film, when directly laminated to an encapsulant layer comprising ethylene-vinyl acetate copolymer, forms a multilayer film with an average peel strength between the transparent film and the encapsulant layer of greater than 2 lbf/in after curing to crosslink the ethylene-vinyl acetate copolymer and then 1000 hrs of damp heat exposure.

2. The transparent film of claim 1 having a transmission of greater than 90% in the visible region of the electromagnetic spectrum.

3. The transparent film of claim 1, wherein said organosilane coupling agent treated surface is formed by applying a solution of said organosilane coupling agent to said tetrafluoroethylene-hexafluoropropylene copolymer layer and drying.

4. The transparent film of claim 3, wherein said solution of said organosilane coupling agent comprises polar organic solvent.

5. The transparent film of claim 4, wherein said polar organic solvent comprises an alcohol comprising 8 or fewer carbon atoms.

6. The transparent film of claim 1, wherein said organosilane coupling agent treated surface comprises an aminosilane.

7. The transparent film of claim 6, wherein said aminosilane comprises 3-aminopropyltrimethoxysilane, 3-aminopropyltriethoxysilane, N,N′-bis[(3-trimethoxysilyl)propyl]ethylenediamine, N-(2-aminoethyl)-3-aminopropyltrimethoxysilane, N-2-(vinylbenzylamino)-ethyl-aminopropyltrimethoxysilane), or mixtures thereof.

8. The transparent film of claim 1, wherein said tetrafluoroethylene-hexafluoropropylene copolymer layer has a thickness in the range of 10 to 200 microns.

9. A weatherable multilayer film comprising:
a transparent film comprising a tetrafluoroethylene-hexafluoropropylene copolymer layer having an organosilane coupling agent treated surface; and
an encapsulant layer directly laminated to said treated surface of said transparent film, wherein an average peel strength between said transparent film and said encapsulant layer is greater than 2 lbf/in after 1000 hrs of damp heat exposure, with the proviso that when the encapsulant layer comprises ethylene-vinyl acetate copolymer, the multilayer film is cured to crosslink the ethylene-vinyl acetate copolymer prior to 1000 hours of damp heat exposure.

10. The weatherable multilayer film of claim 9, wherein said organosilane coupling agent treated surface of said transparent film is formed by applying a solution of said organosilane coupling agent to said tetrafluoroethylene-hexafluoropropylene copolymer layer and drying.

11. The weatherable multilayer film of claim 10, wherein said solution of said organosilane coupling agent comprises polar organic solvent.

12. The weatherable multilayer film of claim 11, wherein said polar organic solvent comprises an alcohol comprising 8 or fewer carbon atoms.

13. The weatherable multilayer film of claim 9, wherein said organosilane coupling agent treated surface comprises an aminosilane.

14. The weatherable multilayer film of claim 13, wherein said aminosilane comprises 3-aminopropyltrimethoxysilane, 3-aminopropyltriethoxysilane, N,N′-bis[(3-trimethoxysilyl)propyl]ethylenediamine, N-(2-aminoethyl)-3-aminopropyltrimethoxysilane, N-2-(vinylbenxzylamino)-ethyl-aminopropyltrimethoxysilane) or mixtures thereof.

15. The weatherable multilayer film of claim 9, wherein said encapsulant layer comprises a polymeric material selected from the group consisting of acid copolymers, ionomers of acid copolymers, ethylene-vinyl acetate copolymers, poly(vinyl acetals), polyurethanes, polyvinylchlorides, polyethylenes, polyolefin block elastomers, copolymers of α-olefins and α,β-ethylenically unsaturated carboxylic acid esters, silicone elastomers, epoxy resins, and combinations of two or more thereof.

16. The weatherable multilayer film of claim 15, wherein said encapsulant layer comprises an ethylene-vinyl acetate copolymer.

17. The weatherable multilayer film of claim 9, wherein said encapsulant layer further comprises an organosilane coupling agent that may be the same or different than the coupling agent used to provide the treated surface of the tetrafluoroethylene-hexafluoropropylene copolymer film.

18. An integrated frontsheet for a photovoltaic module comprising the weatherable multilayer film of claim 9.

19. A photovoltaic module comprising the integrated frontsheet of claim 18.

20. A photovoltaic module comprising:
a frontsheet comprising a transparent film comprising a tetrafluoroethylene-hexafluoropropylene copolymer layer having an organosilane coupling agent treated surface;
a front encapsulant layer;
a cell layer; and
a backsheet,
wherein said front encapsulant layer is directly laminated to said treated surface of said frontsheet, wherein an average peel strength between said frontsheet and said encapsulant layer is greater than 2 lbf/in after 1000 hrs of damp heat exposure.
